(19) United States
(12) Patent Application Publication
(10) Pub. No.: US 2020/0373224 A1
(43) Pub. Date: Nov. 26, 2020

(54) THROUGH-SILICON VIAS AND DECOUPLING CAPACITANCE

(71) Applicant: Microsoft Technology Licensing, LLC, Redmond, WA (US)

(72) Inventors: Gregory M. Daly, Seattle, WA (US); William Paul Hovis, Sammamish, WA (US)

(21) Appl. No.: 16/418,038

(22) Filed: May 21, 2019

(51) Int. Cl. H01L 23/48; H01L 23/00; H01L 23/522; H01L 25/16; H01L 49/02; H01L 21/768

(52) U.S. Cl. CPC H01L 23/481; H01L 24/09; H01L 24/17; H01L 23/5223; H01L 2924/30105; H01L 28/40; H01L 21/76898; H01L 2924/1205; H01L 2924/14; H01L 25/16

(57) ABSTRACT

Integrated circuit decoupling capacitance systems, arrangements, and assemblies are discussed herein. In one example, an assembly includes an integrated circuit device comprising a plurality of through silicon vias (TSVs) coupled to corresponding voltage domains of the integrated circuit device. The assembly includes one or more capacitive elements external to the integrated circuit device and conductively coupled to selected ones of the TSVs.

### BACKGROUND

Integrated circuit devices, such as central processor devices, graphics processors, or system-on-a-chip (SoC) devices can be employed in computing systems. These integrated circuit devices can have one or more voltage domains which correspond to particular power distribution subdivisions within the integrated circuit device. In large integrated circuit devices, operating frequency is a significant design concern, and many times an increased operating frequency is desired. However, a major barrier to increasing integrated circuit operating frequency is transient response and stability of the voltage domains supplying various processing units that form the integrated circuit device. These processing units, among other on-die components, can have power demands that vary rapidly and across a large power consumption range. As these power demands change quickly over time, voltage levels can experience dips or spikes, potentially leading to operational failures of at least the processing units.

Decoupling capacitors can be employed to reduce some transient effects related to these power demands Unfortunately, placement of decoupling capacitors on nearby circuit boards can lead to other sets of problems, and is limited in effectiveness because such placement is relatively far away in electrical terms to target circuitry. For example, inductance from interconnect and positioning between the decoupling capacitors and the target circuitry limits the effectiveness of the decoupling capacitors. Moreover, these decoupling capacitors take up valuable circuit real estate, complicate circuit placement and routing, and can unintentionally space apart processing units or other functional elements leading to less than ideal performance.

### OVERVIEW

Integrated circuit decoupling capacitance systems, arrangements, and assemblies are discussed herein. In one example, an assembly includes an integrated circuit device comprising a plurality of through silicon vias (TSVs) coupled to corresponding voltage domains of the integrated circuit device. The assembly includes one or more capacitive elements external to the integrated circuit device and conductively coupled to selected ones of the TSVs.

In another example, a semiconductor capacitance device is discussed. This semiconductor capacitance device includes an integrated array of semiconductor capacitors, and a metallization layer configured to conductively couple selected semiconductor capacitors into voltage domain groupings. The semiconductor capacitance device also includes conductive pads disposed on a surface of the semiconductor capacitor device and configured to couple to TSV features of an external integrated circuit.

This Overview is provided to introduce a selection of concepts in a simplified form that are further described below in the Detailed Description. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates an integrated circuit arrangement in an implementation.

FIG. 2 illustrates an integrated circuit arrangement in an implementation.

FIG. 3 illustrates an integrated circuit arrangement with voltage domain groupings in an implementation.

FIG. 4 illustrates a detailed side view of an integrated circuit arrangement in an implementation.

FIG. 5 illustrates a detailed side view of an integrated circuit arrangement in an implementation.

FIG. 6 illustrates a semiconductor wafer and capacitance array in an implementation.

FIG. 7 illustrates a method of forming an integrated circuit arrangement in an implementation.

### DETAILED DESCRIPTION

In integrated circuit devices, such as system-on-a-chip (SoC) and processor designs, operating frequency can be a significant operating parameter. A major roadblock to increasing processor frequency is the transient response and stability of the voltage rails supplying execution units of the processor. Thus, an effective strategy is desired to decrease the influence of high frequency voltage transient events, such as dips or droops, among other transient events. A simple tool to evaluate the effectiveness of a decoupling capacitor can be measuring a path that electrical current takes when traveling to a capacitor and back. The area inside this path or loop translates to inductance, and this inductance limits the frequencies over which the capacitor can be effective for decoupling purposes.

As mentioned above, decoupling capacitors can be positioned on a main circuit board around a perimeter of an SoC. However, this positioning can still leave relatively long distances between the decoupling capacitors and the target circuitry, which can have associated inductance and further exasperate the negative influences of transient events. Main board decoupling capacitors are typically too far away from an affected circuit and have too much inductance to relieve very fast transients on SoC devices. Some decoupling capacitors are placed in a land-side configuration on a die carrier, referred to as land-side capacitors (LSCs). These land-side capacitors are placed on a circuit board package that carries the die, but underneath the die shadow. In recent SoC and processor designs, these land-side capacitors have fallen out of popularity, as using them prevents a package designer from placing solder pads/balls for the die in the area directly underneath the die, and makes routing circuit board traces more complex. This increases a size of the die carrier (costing more) and also compromises power delivery of a main board voltage regulator system. Thus, die-side carrier perimeter decoupling capacitors have been employed instead, referred to as die-side capacitors (DSCs). These are decoupling capacitors placed on a top side of the die carrier, around a perimeter adjacent to the semiconductor die. An examination of the associated current loops indicate that these DSCs are less effective than LSCs because the associated capacitor distance is much greater from the die. For this reason, DSCs struggle to contribute effectively to voltage droop mitigation.

Another solution is to integrate capacitance into the same die as the integrated device itself. Since capacitance is directly related to unit area, any addition of capacitive structures on the die results in more die area. Thus, this technique is typically an expensive venture leading to larger dies and increasing costs. Also, on-die decoupling capacitors take up valuable circuit real estate, complicate fabrication, and can unintentionally space apart processing units or other functional elements leading to logic routing and placement complications. High-performance processors are often built using the latest fabrication technology and smallest feature sizes, and thus are the most expensive to manufacture, so any increase in die area for capacitance also increases the total integrated circuit cost dramatically. Adding capacitance structures to make the die larger also can create challenges for semiconductor designers, since capacitance structures can displace functional logic or processing cores, and affected signals must travel farther. This can lead to difficulty in placement and routing, as well as establishing proper timing relationships among logic/cores.

In the examples herein, several example implementations of enhanced decoupling capacitance structures and arrangements are discussed. In these examples, through-silicon vias (TSVs) are employed to attach decoupling solutions onto an integrated circuit die very near to the affected integrated circuits and voltage domains. In one implementation, a semiconductor die matched closely to a size of the SoC/processor die would be manufactured, and comprised of capacitive structures. This capacitance die can be physically coupled onto the processor die. This capacitance die could also be manufactured with fewer steps and on an older manufacturing process. Advantageously, this capacitance-focused die per-square-unit area could be produced for a much lower cost than that of the die of the processor or SoCs, effectively reducing an on-die capacitance cost. In a second implementation, small chip capacitors or discrete surface mount capacitors could be directly attached to the TSVs and onto an associated integrated circuit die.

When a separately produced capacitance die comprised of capacitance structures is employed, a large semiconductor wafer of regularly arrayed capacitance structures can be formed. This wafer can be separated into variously sized capacitance chip arrangements, using dicing channels which form a regular gridded structure with regard to the capacitance elements. This can lead to increased utilization of the wafer itself. For example, the capacitive structures and their corresponding connection pads could be arranged in 1 millimeter (mm) by 1 mm square tiles, with dicing channels between them. In this manner, a common underlying wafer design can be customized using one or more personalization layers and sliced into individual dies for a particular target integrated circuit device. A common wafer design can be re-used for capacitance chips different shapes and sizes. One or more final personalization layers can customize the wafer and gridded capacitance design to subdivide the wafer design into a quantity of ‘X’ mm by ‘Y’ mm integrated capacitor solutions that provide for the decoupling needs of specific target integrated circuit devices.

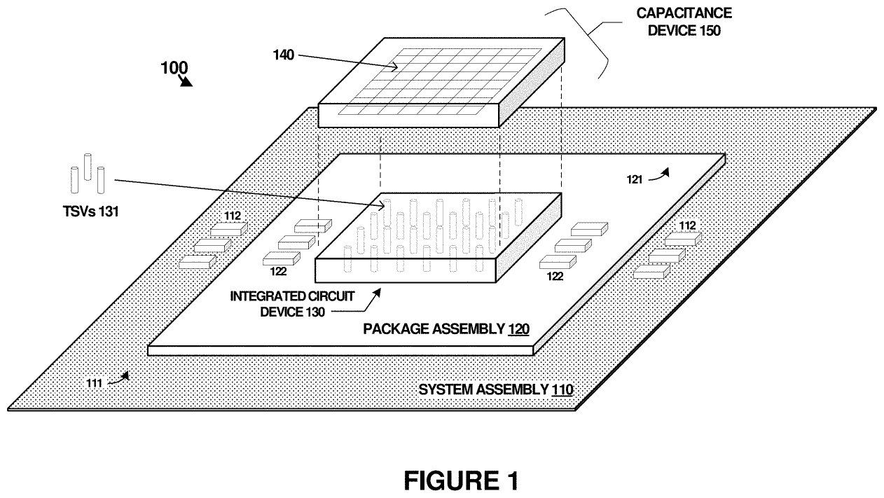

Turning now to a first example implementation, FIG. 1 is presented. FIG. 1 illustrates an integrated circuit arrangement 100 in an implementation. In FIG. 1, circuit board 111 of system assembly 110 is coupled to package assembly 120. Package assembly comprises carrier 121 for integrated circuit device 130. Capacitance device 150 comprises a semiconductor die separate from that of integrated circuit device 130, and is comprised of individual capacitance structures 140. Capacitance device 150 can be placed onto integrated circuit device 130, as will be discussed below.

In typical configurations, integrated circuit device 130 comprises various processing cores, interfacing logic, power distribution structures, and the like. Integrated circuit device 130 is bonded or otherwise coupled to carrier 121 of package assembly 120. Together, package assembly with integrated circuit device 130 might comprise a system-on-a-chip (SoC), central processing unit (CPU), or graphics processing unit (GPU), among other integrated devices. This integrated device can be coupled to a system board, such as a motherboard or daughterboard comprising circuit board 111 for integration into a computing system. Various support circuitry, such as memory, storage, peripherals, power supplies, and other related circuitry, can be included on such a system board. System assembly 110 can comprise this system board, as well as other components.

In operation, dynamic power demands and electromagnetic interference concerns might warrant one or more sets of decoupling capacitors. Various decoupling capacitors can be placed onto system assembly 110 and package assembly 120, such as around perimeters of integrated circuit device 130 and package assembly 120. In FIG. 1, a first set of decoupling capacitors 112 are positioned onto circuit board 111. A second set of decoupling capacitors 122 are positioned onto package assembly 120. Decoupling capacitors 112 and 122 can reduce voltage fluctuations due to transient effects of integrated circuit device 130, as well as reduce susceptibility and emissions with regard to electromagnetic interference. However, due to the distances between decoupling capacitors 112 and 122 and relevant portions of integrated circuit device 130, relatively large current loops can be formed, leading to increased inductance on the affected voltage links of included power domains. These inductances, among other factors, can limit the transient speeds or maximum frequencies over which decoupling features are effective. When these decoupling features are not sufficient to reduce transients on voltage links, such as droops, dips, and spikes, among other transient events, then operation of integrated circuit device 130 can be reduced. Failures can even result during larger transient events and dynamic changes in power demands of integrated circuit device 130.

One potential way to compensate for voltage dips and droops is to increase a level of a voltage supplied the various power domains of integrated circuit device 130. For example, if a particular voltage domain specifies 1.00 VDC, then an increase to 1.05 VDC or 1.10 VDC might aid tolerance of integrated circuit device 130 to various voltage dips. However, this not only can waste energy, but lead to higher power dissipation within integrated circuit device 130, and thus increased heating.

In FIG. 1, instead of increasing a supply voltage level, or altering a quantity or arrangement of capacitors on circuit board 111 or package assembly 120, an enhanced arrangement is shown. Specifically, FIG. 1 shows a separate capacitance device 150 which is positioned onto integrated circuit device 130. Capacitance structures 140 of capacitance device 150 can be individually connected to power features of integrated circuit device 130. Capacitance structures 140 can be connected using one or more through-silicon vias (TSVs) incorporated into integrated circuit device 130. In this manner, capacitance device 150 can be positioned very near power features of integrated circuit device 130 to significantly decrease any distance between capacitance structures and affected power features. Any inductive loop distance/area can also be correspondingly reduced, leading to faster transient response for voltage domains. Thus, an actual supplied voltage level experiences much smaller deviations from a desired voltage level or circuit minimum voltage levels. Such assemblies formed with capacitance device 150 and integrated circuit device 130 can improve a minimum voltage (Vmin) needed to supply a particular integrated circuit by 50-100 mV or more which translates into a 10-20% improvements in device power efficiency. If desired, these efficiency gains in Vmin operation can be translated into supplying a lower voltage level to the affected circuit, which can reduce power dissipation and increase performance for a particular operating frequency.

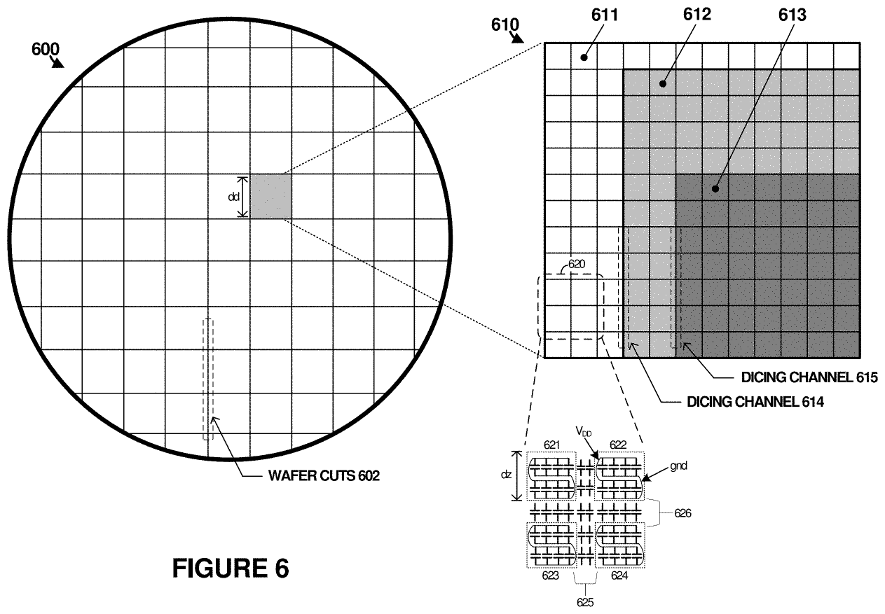

FIG. 1 employs a specialized capacitance “chip” shown as capacitance device 150 having a plurality of individual capacitors formed by capacitance structures 140. Capacitance device 150 includes a semiconductor capacitor array comprising an integrated array of metal-oxide-semiconductor, metal-insulator-semiconductor, silicon (source, drain, and channel), or silicon gate (oxide/insulator) capacitance elements. Other forms and types of semiconductor-based capacitive elements can be employed. Capacitance structures 140 comprise this semiconductor capacitor array, and other semiconductor structures can be included, such as transistors and interconnect. In the examples herein, various interconnect is included to form groupings or personalized configurations among capacitance structures 140. As will be discussed below in FIG. 6, interconnect can also be included to couple capacitance structures located within unused dicing channels of capacitance structures 140. Additionally, interconnect is employed to couple terminals of various capacitance structures 140 to external interconnection features, such as conductive pads or external interfacing elements.

Capacitance device 150 can be coupled mechanically and electrically to integrated circuit device 130 using external features included on both capacitance device 150 and integrated circuit device 130, such as conductive pads. Solder bumps or controlled collapse chip connection (C4) bumps can be employed to couple pads of integrated circuit device 130 to pads of capacitance device 150. Capacitance device 150 can be bonded to integrated circuit device 130 in a “flip-chip” configuration, where a top side of capacitance device 150 comprises the conductive pads for coupling to pads of integrated circuit device 130. Moreover, integrated circuit device 130 can be in a flip-chip configuration for bonding of a top-side of integrated circuit device 130 to package carrier 120, and with a bottom-side of integrated circuit device 130 comprising the conductive pads to couple to capacitance device 150. In this matter, a direct connection through associated bumps can be established between integrated circuit device 130 and capacitance device 150. It should be understood that the flip-chip configuration need not be employed to couple integrated circuit device 130 and capacitance device 150, and the top-side/bottom-side terminology is merely exemplary.

The external pads of integrated circuit device 130 are further conductively coupled to associated TSVs 131 included in integrated circuit device 130. TSVs 131 are conductively coupled to various power domains and power features within integrated circuit device 130. TSVs 131 are formed during or after fabrication of integrated circuit device 130 using various manufacturing techniques to etch, drill, or otherwise penetrate through several layers of integrated circuit device 130 to form a conductive link between a desired power layer/domain and an externally-facing chip interface via a conductive pad.

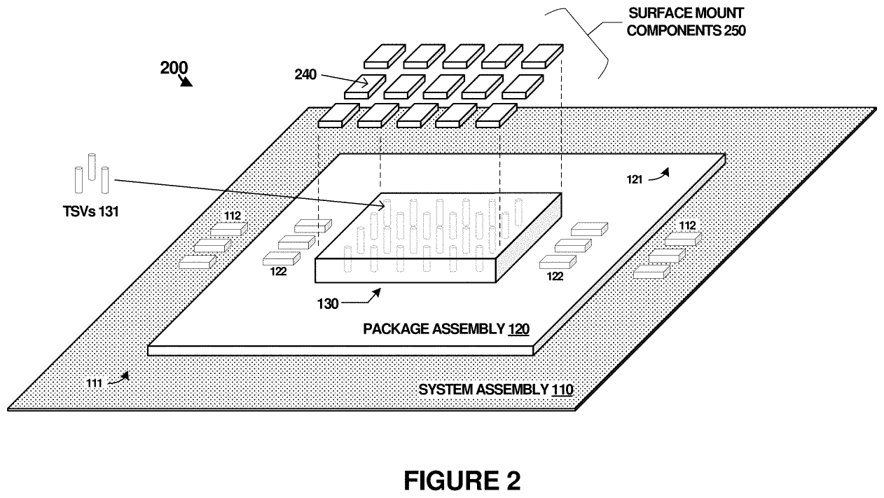

While FIG. 1 illustrates an integrated capacitance example in capacitance device 150, other examples can be employed. FIG. 2 illustrates one additional example 200 using discrete capacitors 240 as a part of an enhanced surface mount capacitor arrangement 250. In FIG. 2, discrete capacitors 240 are positioned onto conductive pads coupled to TSVs 131 of integrated circuit device 130. Thus, an integrated capacitance device is not employed as in FIG. 1. Discrete capacitors 240 can comprise surface mount capacitors, such as “0204” size capacitors, or other various sizes of surface mount capacitors. These surface mount capacitors can be bonded using reflow soldering or similar techniques to conductively couple individual capacitors to external conductive pads of integrated circuit device 130.

There is a manufacturing and monetary cost associated with employing TSVs 131, such as for manufacturing processing that must be added to integrated circuit device 130. However, the advantages of using TSVs 131 along with capacitance device 150 can outweigh any additionally complexity in using TSVs 131. Moreover, personalization or customization among the electrical connections made between capacitance elements and integrated circuit device power features can be achieved. This personalization can comprise differences in metallization layering or interconnect features included in capacitance device 150 (when employed) or in one or more layers of integrated circuit device 130 when discrete capacitors are employed. In the examples below, various examples of this personalization will be discussed.

Turning now to a detailed discussion on the elements of FIGS. 1 and 2, system assembly 110 comprises one or more printed circuit boards (PCBs) or circuit card assemblies (CCAs) formed using various circuit board manufacturing processes. System assembly 110 can comprise a computing system motherboard or daughterboard in many examples. System assembly 110 can include circuit boards as well as components mounted to the circuit boards. In FIGS. 1 and 2, system assembly 110 includes exemplary circuit board 111, although other configurations are possible. Circuit board 111 can comprise fiber-infused dielectric materials, such as fiberglass, FR4, or various composite materials. Circuit board 111 comprises two surfaces or sides as well as several layers of alternating insulating board material and conductive interconnect or traces formed with metal etchings or printed conductive features. Circuit board 111 can include one or more power distribution layers/planes or grounding layers/planes which form one or more layers of the associated circuit board. Circuit board 111 can include conductive vias which can penetrate an entire layered stackup of circuit board 111 or a subset of layers, which may or may not include hidden or buried vias. Circuit board 111 can include labeling/screen printing, solder mask material, and chassis mounting features.

Decoupling capacitors 112 can be included on circuit board 111 within system assembly 110. Capacitors 112 can comprise surface mount, multilayer ceramic capacitors (MLCCs), through-hole, or other types of discrete capacitors. Similarly, capacitors 122 can comprise similar types of capacitors as capacitors 112. Capacitors 112 and 122 can be of various sizes, such as 0603 or 0402 size surface mount capacitors, among others.

Package assembly 120 comprises an integrated circuit package which includes a carrier comprising a printed circuit board, typically smaller than that of system assembly 110. Package assembly 120 can comprise similar materials as system assembly 110, such as layers of insulating and conductive materials with associated traces, planes, routing, vias, and the like. Package assembly 120 couples to system assembly 110 via one or more solder bumps or solder features, such as controlled collapse chip connection (C4) balls. Typically pins and sockets are not employed for package assembly 120, but in some examples are possible. Package assembly 120 can comprise a flip-chip assembly when fitted with an associate die of an integrated circuit, such as integrated circuit device 130. Package assembly 120 has a first surface or side (referred to as a die side) which couples to integrated circuit device 130 and a second surface or side (referred to as a land side) which couples to a system assembly PCB via solder features, such as solder balls.

Integrated circuit device 130 comprises a microprocessor, central processing unit (CPU), graphics processing unit (GPU), system-on-a-chip (SoC), application-specific integrated circuit (ASIC), field-programmable gate array (FPGA) tensor processing unit (TPU), or baseband processing unit (BBU), among other analog and digital integrated circuits. Integrated circuit device 130 is formed using various semiconductor manufacturing processes, such as employed in semiconductor wafer fabrication. Integrated circuit device 130 can comprise silicon-based circuit, but might also include other types of semiconductor materials as well as associated conductive interconnect. Integrated circuit device 130 includes various layers, logic devices, interconnect, metallization, processing cores, and interfacing circuitry. Integrated circuit device 130 comprises one or more power domains, each having a characteristic voltage level. Integrated circuit device 130 can comprise a flip-chip design which has external pads on a top side of chip (with regard to a manufacturing directionality), and is coupled to carrier 121 of package assembly 120 via solder features/balls, C4 balls or other bonding processes. Integrated circuit device 130 can include TSVs, which might penetrate an entire thickness of integrated circuit device 130. TSVs can optionally couple to power/voltage domain interconnect/planes or power distribution features integrated into integrated circuit device 130.

Although discussed above, capacitance device 150 can also comprise a wafer-fabricated integrated circuit. Typically, capacitance device 150 only comprises capacitance structures and interconnect, but might also include various active and passive circuitry to support the capacitance structures. Capacitance device 150 can include interconnect to couple capacitance structures into groups or zones, and can include interconnect to couple non-zoned capacitance structures into an adjacent zone. Capacitance device 150 can include conductive pads on a ‘top’ side to couple to TSVs of integrated circuit device 130 via solder features in a stacked integrated circuit process. Capacitance device 150 can be a thinned device where a back or bottom substrate portion is shaved or etched thinner to reduce a thickness for enhanced thermal dissipation or reduction in stackup height.

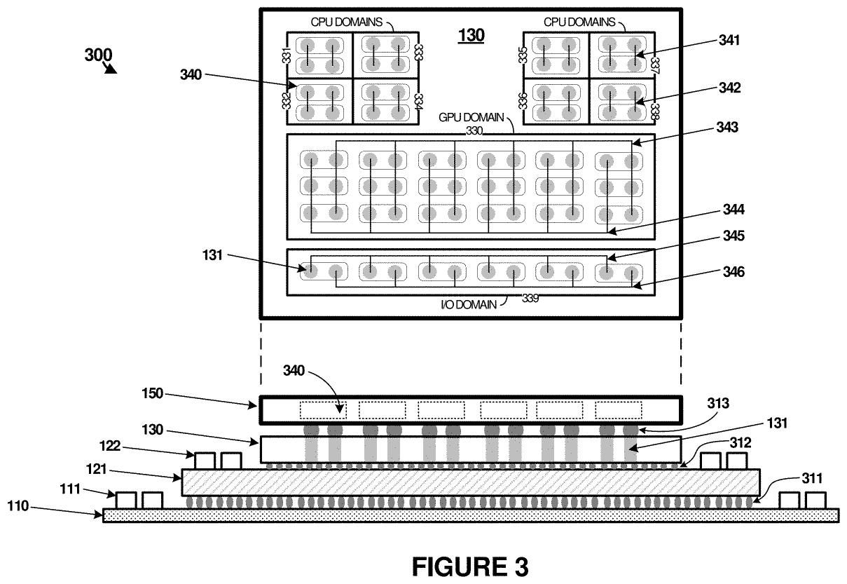

FIG. 3 illustrates integrated circuit arrangement 300 with voltage domain groupings in an implementation. FIG. 3 includes a side view of arrangement 300 to illustrate a stackup among system assembly 110, package assembly 120, integrated circuit device 130, and capacitance device 150. FIG. 3 includes a top view of integrated circuit device 130 to illustrate power domains and associated interconnect with respect to capacitance structures of capacitance device 150. Although similar elements as found in FIGS. 1 and 2 are shown in FIG. 3, it should be understood that other elements can instead be included. Also, at least the (through-silicon via) TSV elements in FIG. 3 are not drawn to scale, and instead are sized to enhance clarity in the associated discussion.

FIG. 3 shows a stackup of elements which form an assembly. At a bottom of the stackup in FIG. 3, system assembly 110 is shown having one or more perimeter decoupling capacitors 111. Further circuitry can be included in system assembly 110, such as memory, storage, peripherals, power circuitry, and other similar elements. These are not shown in FIG. 3 for clarity. Integrated circuit device 130 comprises a semiconductor die which is bonded to carrier 121 of package assembly 120. This configuration might comprise a flip-chip configuration, although other configurations are possible. Solder balls 312 couple integrated circuit device 130 to carrier 121 to form package assembly 120, along with other circuit which might include perimeter decoupling capacitance 122. Package assembly 120 is also coupled using solder balls 311 to system assembly 110.

In FIG. 3, a top side of integrated circuit device 130 is shown with multiple power domains that correspond to circuit areas where integrated circuits are formed. The grey dots in FIG. 3 each represent a TSV 131 (through-silicon via) which is connected to voltage domains as indicated by corresponding boxes. In other examples, the TSVs are much smaller than pictured, and the grey dots can instead represent conductive pads to which individual TSVs are connected. These grey dots may also connect to multiple power supply or ground TSVs in the corresponding areas. This example shows 8 separate CPU power domains 331-338, one graphics/GPU power domain 330, and one input/output (I/O) power domain 339 associated with memory interface circuits and other external interfaces. Other power domains are possible, but this example shows various areas that can benefit from additional decoupling capacitance, due in part to having dynamic operation with high power demand and susceptibility to voltage transients. Some areas of the device may be somewhat immune from such concerns, due to either low power demands overall or having consistent power demand that varies little and thus corresponds to low power supply noise.

In the example shown in FIG. 3, individual capacitors or capacitance zones 340 are represented by the rounded rectangles that span across two or more TSVs. In one example implementation, capacitance zones 340 comprise regions of an integrated capacitive device, such as discussed for capacitive device 150 in FIGS. 1 and 2. In such an example, no discrete capacitors would be used. Capacitive device 150 can be personalized to create the separate capacitance zones among groups of capacitance elements, such as groups of individual semiconductor capacitors. Each of these zones would be further coupled together with a personalization or customization metallization interconnect indicated by personalization lines 341-346 coupling individual TSVs/capacitance elements. In other examples, the grey dots in FIG. 3 can represent connections between capacitance device 150 and integrated circuit device 130. The interconnect along with the grey dots could connect to multiple underlying TSVs, with some connected to a power supply side of the capacitor areas and some to a ground side of the capacitor areas. Conductive pads can be created to connect to solder bumped TSVs on the top side of integrated circuit device 130. Capacitance device 150 can be mechanically and electrically coupled to integrated circuit device 130 using solder bumps 313. A heat sink can also be added onto capacitance device 150 in the stackup, with any appropriate thermal paste provided between capacitance device 150 and the heat sink.

In FIG. 3, capacitance zones 340 can each comprise a plurality of capacitance elements, such as semiconductor capacitors provided by capacitance device 150. FIG. 6 shows example implementations of these capacitance elements, but FIG. 3 may show further personalization interconnect absent from FIG. 6. Capacitance elements of individual capacitance zone 340 are coupled together at common electrical terminals, such as connecting all capacitance elements of the zone at a positive terminal to V_{DD} and at a negative terminal to ground, among other voltage configurations. Then, personalization lines 341-346 can be used to couple individual capacitance zones together and correlate these zones to particular voltage/power domains of integrated circuit device 130. For each capacitive zone, one set of personalization lines is coupled to a supply voltage (such as V_{DD}) and another set of personalization lines is coupled to a reference voltage (such as ground). For example, line 343 can be coupled to V_{DD}, while line 344 can be coupled to ground. In this manner, decoupling capacitance is positioned very close to affected circuitry of integrated circuit device 130, and individual capacitance zones 340 can be grouped or lumped together for individual voltage/power domains. TSVs of integrated circuit device 130 would couple over conductive pads and solder bumps 313 to capacitance zones 340 through any associated personalization lines.

In another implementation example, capacitance zones 340 can comprise discrete capacitors, such as 0201-sized surface mount capacitors, among other discrete capacitor types discussed herein. When discrete surface mount capacitors are employed, these discrete capacitors would be similar to that seen in FIG. 2 for capacitors 240, although variations are possible. These discrete capacitors can be soldered to the ‘top’ side in FIG. 3 of integrated circuit device 130, and appropriate solder bumps 313 would be patterned on top of integrated circuit device 130 to provide an electrical connection to the capacitors. Any personalization lines might be omitted when discrete capacitors are employed, or this personalization can be achieved using one or more metallization layers in integrated circuit device 130. A heat sink with appropriate surface indentations corresponding to where the capacitors are positioned can be secured on top of integrated circuit device 130. Thermally conductive material also can be included between the heat sink and integrated circuit device 130.

A final assembly having elements 110, 120, 130, capacitance elements (discrete capacitors 240 or capacitance device 150), and a heat sink would provide substantially improved power supply decoupling for integrated circuit device 130 that allows for improved performance and/or reduced power supply voltages due to decreased power supply noise. This can also lead to improved circuit operating voltage minimum (Vmin) values by having less dynamic variation in voltage levels provided to the individual power domains.

In both integrated capacitance and discrete capacitance examples, integrated circuit device 130 could be a thinned device which might improve thermal dissipation characteristics of the integrated circuit device 130, as well as expose features of associated TSVs for conductive coupling. Capacitance device 150 could also be thinned to reduce additional thermal impedance imposed by placing another die onto integrated circuit device 130. In either case of integrated capacitance and discrete capacitance, a final integrated assembly might exhibit slightly degraded thermal performance as compared to an assembly without TSV-provided capacitance, but this degraded thermal performance can largely be offset by integrated circuit device 130 operating at a lower power level provided by lower voltage minimums. The closely-positioned decoupling capacitance can lead to better dynamic performance on any associated voltage lines and voltage domains of integrated circuit device 130, allowing for lower operating voltages for the domains of integrated circuit device 130, and hence lower power. Any voltage optimization techniques which might be applied to reduce supply voltages to integrated circuit device 130 can also benefit from this closely-positioned decoupling capacitance. Specifically, a reduced magnitude of transient effects on voltage domains from the close decoupling capacitance can also correspond to reduced voltage levels needed to be supplied to a given circuit.

A final assembly having integrated circuit device 130 and capacitance device 150 might have additional stacked integrated circuits or semiconductor devices, such as memory devices, further processors, additional capacitance chips, and the like. Additional TSVs can be included within capacitance device 150 to accommodate connections to power supply domains and other signaling between integrated circuit device 130 and the additional stacked chips. At some amount of additional stacked devices, the stackup may be limited by the total power consumption of all stacked devices and the ability to remove heat from the structure. Capacitive device 150 might located at any vertical position in the stackup or sandwich of integrated devices, such as in a middle or top layer. Using an inner layer of the stack might be the more appropriate to keep the effectiveness of the decoupling capacitance, but applications and designs can vary. In fact, more than one capacitance device 150 might be included in larger stackups.

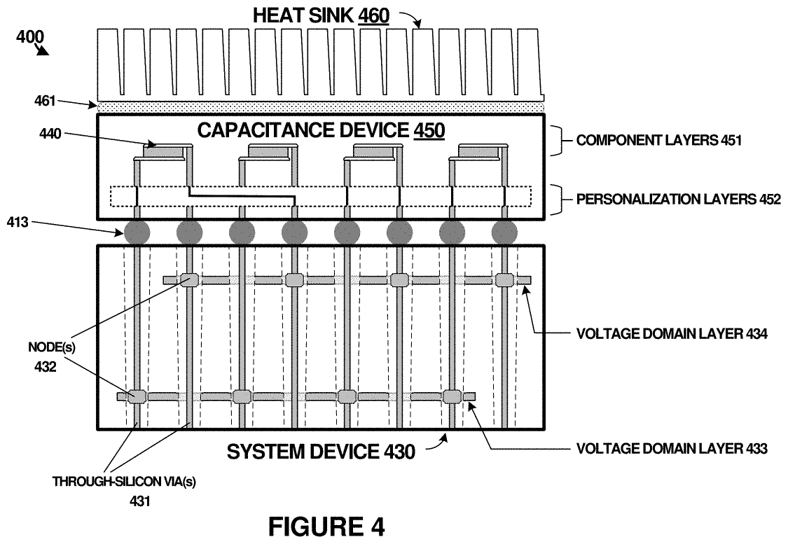

FIG. 4 illustrates a detailed side view of integrated circuit arrangement 400 in an implementation. Elements of FIG. 4 can be examples of similar elements in FIGS. 1-3, although variations are possible. In FIG. 4, a portion of a stackup of system device 430 and capacitance device 450 is shown. Various elements, such as the (through-silicon via) TSV elements in FIG. 4 are not drawn to scale, and instead are sized to enhance clarity in the associated discussion. Also, the quantity and sizing of layers of system device 430 and capacitance device 450 are merely exemplary, and would vary in actual implementations.

System device 430 can comprise any integrated circuit device discussed herein, such as SoCs, CPUs, and the like. Capacitance device 450 comprises an integrated device with a plurality of semiconductor capacitance structures, such as discussed for capacitance device 150. A cross-sectional view of this vertical stackup is shown in FIG. 4, with system device 430 bonded to capacitance device 450 using a plurality of solder bumps 413. Conductive pads on system device 430 and capacitance device 450 make contact with solder bumps 413 for electrical and mechanical coupling.

Heat sink 460 can also be included, and bonded to capacitance device 450 using thermal paste, thermal pads, or other thermal bonding materials. This thermal bonding is shown as element 461 in FIG. 4.

System device 430 includes various internal circuitry, logic, interconnect, and other fabricated devices, elements, and structures. However, for clarity in FIG. 4, only exemplary power distribution structures are shown. Two voltage domain layers 433-434 are shown, with a first layer comprising interconnect for a first voltage level and a circuit domain, and a second layer comprising interconnect for a second voltage level for the circuit domain. These voltage levels might comprise V_{DD} and ground, or might comprise other voltage levels depending upon application/implementation. The circuit domain can comprise one of the example domains in FIG. 3, such as a GPU/graphics domain, processing core/CPU domain, or other domains. The domains have voltage distribution interconnect segregated from other domains. It should be understood that each ‘layer’ of FIG. 4 might actually comprise more than one adjacent layer or collection of layers.

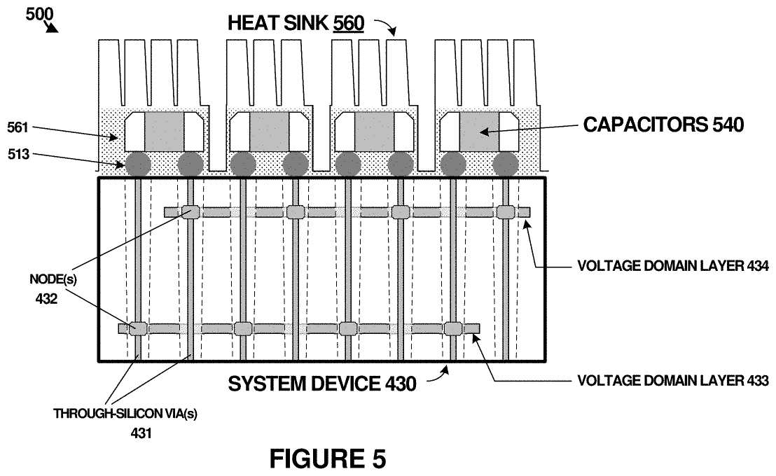

Several through-silicon vias (TSVs) are included in system device 430. In this example, TSVs 431 penetrate an entire vertical thickness within system device 430, but other examples might only have partial penetration. Various connection nodes 432 are employed to couple conductive structures in each TSV to an associated voltage domain layer, thus electrically coupling the particular TSV to the particular voltage domain layer. Although two simplified voltage domain layers are shown in FIG. 4, actual device implementations can have more than one voltage layer in a similar physical layer of system device 430. Moreover, voltage domain layers can exist on multiple layers within system device 430, with individual TSVs connecting to one or more layers. TSVs can also connect to a first layer of metallization nearest to a surface of system device 430 or on a top layer metallization nearest connection pads for an associated package. Each TSV also has a conductive pad (not shown) positioned on a top layer of system device 430 for electrical coupling of the TSV to external components. In this example, the external components include capacitance device 450 through solder balls 413. In FIG. 5, the external components comprise discrete capacitors.

Capacitance device 450 includes a plurality of capacitance structures, which in FIG. 4 are illustrated by exemplary semiconductor capacitors 440. These capacitors 440 are integrated into component layers 451 of a semiconductor structure of capacitance device 450, along with various interconnect. Moreover, personalization layers 452 can be included to provide customized interconnect between a regular grid structure or array of capacitance elements of capacitance device 450 and selected TSVs and power domains. For example, capacitance device 450 might comprise a gridded capacitance structure as seen in FIG. 6. Personalization layers 452 can be employed to couple the capacitance structures into zones of capacitance within capacitance device 450. Personalization layers 450 can also be used to couple these zones of capacitance to individual pairs of TSVs which correspond to a particular voltage domain of system device 430. When dicing channels are employed, such as seen in FIG. 6, capacitance elements in non-cut dicing channels can be assigned using personalization layers 450 to neighboring capacitance zones.

FIG. 5 illustrates a detailed side view of integrated circuit arrangement 500 in an implementation. Elements of FIG. 5 can be examples of similar elements in FIGS. 1-4, although variations are possible. In FIG. 5, a portion of a stackup of system device 430 and capacitors 540 are shown. System device 430 can comprise any integrated circuit device discussed herein, such as SoCs, CPUs, and the like. Capacitors 540 comprise discrete capacitors, such as surface mount capacitors or capacitors 240 in FIG. 2, which may have separate or combined packaging among more than one capacitor. A cross-sectional view of this vertical stackup is shown in FIG. 4, with system device 430 bonded to individual ones of capacitors 540 using a plurality of solder bumps 513. Conductive pads on system device 430 make contact with solder bumps 513 for electrical and mechanical coupling to capacitors 540.

Heat sink 560 can also be included, and bonded to capacitors 540 and system device 430 using thermal paste, thermal pads, or other thermal bonding materials. This thermal bonding is shown as element 561 in FIG. 5. In contrast with heat sink 460 of FIG. 4 which has a generally flat mating interface between capacitance device 450 and heat sink 460, heat sink 560 has a patterned mating surface. This patterned mating surface can be configured to fit positioning or placement of capacitors 540 on system device 430, such as indentations in heat sink 560 provide cavities for capacitors 540 to fit into along with any desired thermal paste or material 561.

System device 430 includes various internal circuitry, logic, interconnect, and other fabricated devices, elements, and structures. However, for clarity in FIG. 5, only exemplary power distribution structures are shown. Two voltage domain layers 433-434 are shown, with a first layer comprising interconnect for a first voltage level and a circuit domain, and a second layer comprising interconnect for a second voltage level for the circuit domain. Although two simplified voltage domain layers are shown in FIG. 5, actual device implementations can have more than one voltage layer in a similar physical layer of system device 430. Moreover, voltage domain layers can exist on multiple layers within system device 430, with individual TSVs connecting to one or more layers. These voltage levels might comprise V_{DD} and ground, or might comprise other voltage levels depending upon application/implementation. V_{DD} and ground domains can also exist over multiple layers within system device 430, which may include layers near a surface of system device 430. The circuit domain can comprise one of the example domains in FIG. 3, such as a GPU/graphics domain, processing core/CPU domain, or other domains. The domains have voltage distribution interconnect segregated from other domains. It should be understood that each ‘layer’ of FIG. 5 might actually comprise more than one adjacent layer or collection of layers.

Several through-silicon vias (TSVs) are included in system device 430. In this example, TSVs 431 penetrate an entire vertical thickness within system device 430, but other examples might only have partial penetration. Various connection nodes 432 are employed to couple conductive structures in each TSV to an associated voltage domain layer, thus electrically coupling the particular TSV to the particular voltage domain layer. Each TSV also has a conductive pad (not shown) positioned on a top layer of system device 430 for electrical coupling of the TSV to external components. In this example, the external components include discrete capacitors 540.

FIG. 6 illustrates semiconductor wafer 600 and capacitance arrays in an implementation. FIG. 6 details construction of a general-purpose capacitive chip structure with a 1 mm, 0.5 mm, or other size of repeating block, referred to as capacitance zones. Wafer 600 comprises a silicon wafer or other semiconductor wafer, including combinations thereof. Wafer 600 can be formed using any associated semiconductor manufacturing techniques. In many examples, wafer 600 can be manufactured using a process or technique which is of an older generation or larger minimum feature size than other integrated circuits, such as a wafer used for integrated circuit device 130 discussed herein. Typically, integrated circuit devices, such as 130 discussed herein, are manufactured using a selected minimum feature size or technology generation. Wafer 600 can be manufactured using a process or technique of an older technology generation or larger minimum feature size than integrated circuit device 130. This can be due in part to capacitance elements being less sensitive to minimum feature size and technology generation. Thus, wafer 600 can be less expensive and more robust to manufacture than integrated circuit device 130.

Wafer 600 comprises an array of semiconductor-based capacitance elements, which are repeated over wafer 600. Wafer 600 can be partitioned into a repeating pattern or grid of subdivisions denoted by dicing channels. Dicing channels are physical features of a wafer which facilitate cutting of the wafer into individual dies, and might comprise channels or grooves. Further isolation spacings can also be included proximate to dicing channels.

In FIG. 6, example wafer cuts 602 are shown of a particular spacing, such as 10 mm or other spacing denoted by example metric “dd” in FIG. 6. Non-square capacitance dies and non-square metrics for “dd” can be employed. Each capacitance die that is cut using wafer cuts 602 comprises a capacitance device, such as capacitance device 150 of FIG. 1. The size of a capacitance die can also correspond to a size of a target integrated circuit device onto which a resultant capacitance die is to be placed. However, wafer cuts 602 can be along any of the dicing channels, and these dicing channels might be gridded at 1 mm or 0.5 mm, among other spacings, denoted by metric “dz” in FIG. 6. Once cut, the individual dies will correspond to the example “dd” metric in FIG. 6, and any added personalization or interconnect layers can span non-cut dicing channels. For a particular wafer design, an underlying capacitance array or grid can be complemented with one or more personalization layers that customize interconnections among capacitance elements. These wafers, once personalized, are then cut according to designated dicing channels to form the desired size/shape of capacitance dies.

Detailed view 610 shows example die sizes along dicing channels. In a first example, die 611 spans twelve (12) dicing channels per wafer cut, and die 611 also comprises a square die. In a second example, die 612 spans nine (9) dicing channels per wafer cut, and die 612 comprises a rectangular die. In a third example, die 613 spans seven (7) dicing channels per wafer cut, and die 613 comprises a square die. Dicing channel 614 can be employed to cut a vertical edge of die 612, while dicing channel 615 can be employed to cut a vertical edge of die 613. It should be understood that other die sizes and shapes can be cut based on the regular pattern of dicing channels over wafer 600.

Turning now to a detailed view of capacitance zones, example view 620 is shown in FIG. 6. View 620 includes an example subset of the total capacitance zones of a die, such as four shown for zones 621-624. Each zone 621-624 comprises a grid or array of individual capacitance zones, shown schematically as capacitors in FIG. 6. Each zone might comprise an analogue to a discrete capacitor or collections of individual sets of capacitors. Each zone is formed with many smaller individual semiconductor capacitors, although a zone might only have one semiconductor capacitor. Actual physical capacitance structures will vary based on the implementation of the capacitance elements, but an arrayed configuration would typically be employed. Capacitance zones can be created by grouping positive terminals (voltage supply or V_{DD}) and negative terminals (ground terminals or gnd) of sets of capacitance elements into commonly connected collections. The coupling of terminals of capacitance structures within each zone might occur within metallization layers used for personalization or other interconnect, or can instead occur within semiconductor layers occupied by or nearby the capacitance elements. Capacitive structures included between zones and within dicing channels 625-626 are not pre-connected to any particular zone. When a die is cut along a particular dicing channel, capacitance elements in that dicing channel are unavailable for use. However, when a die is not cut along a particular dicing channel, then capacitance elements in that dicing channel can be used for adjacent capacitance zones, according to any personalization layers employed. Capacitance elements in the dicing channels can be assigned to a particular zone using personalization interconnect discussed herein, such as one or more metallization layers of wafer 600 or external interconnect.

In addition to connecting terminals of individual capacitance elements to form capacitance zones, individual capacitance zones can be further coupled together using one or more layers of interconnect to form capacitance domains. These capacitance domains can be configured to correspond to power/voltage domains of a target integrated circuit device. Thus, when a capacitance device is mounted to a target integrated circuit device, the capacitance domains comprising one or more capacitance zones can be aligned with power/voltage domains of the target integrated circuit device and share commonly connected voltage/ground rails. Conductive pads are formed to couple to the interconnect and allow the capacitance device to electrically couple to solder features which further couple to TSVs of the target integrated circuit device. The interconnect and conductive pads can be formed using one or more layers of metallization or similar conductive material on wafer 600. The interconnect and conductive pads can form the personalization discussed herein. Moreover, individual capacitance elements located in dicing channels which are not cut may be associated with a neighboring capacitance zone using the interconnect to increase the capacitance of the neighboring capacitance zone.

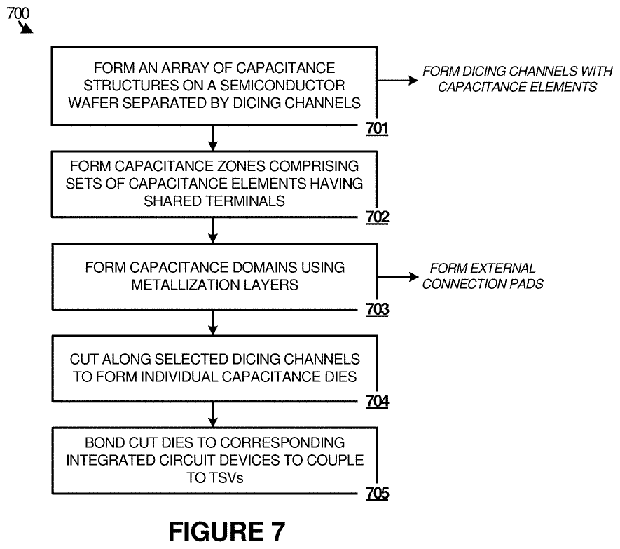

FIG. 7 illustrates example method 700 of forming an integrated circuit arrangement in an implementation. In FIG. 7, the method includes forming (701) an array of capacitance structures on a semiconductor wafer separated by dicing channels. These capacitance structures comprise semiconductor capacitors formed using integrated circuit fabrication processes, such as silicon-based capacitance elements, metal-oxide-semiconductor capacitance elements, or metal-insulator-semiconductor capacitance elements, including variations and combinations thereof. The array is formed over a semiconductor wafer to create a repeating pattern of capacitance elements. Within that repeating pattern, dicing channels can be formed to aid in cutting the wafer into individual dies. These dicing channels also can have individual capacitance elements formed therein. The capacitance elements within the dicing channels might be of a different type, size, or configuration than those not formed in the dicing channels. The dicing channels can be included at a regular interval over the wafer to provide for cutting of the wafer into dies of various sizes and rectangular/square shapes, depending upon the target integrated circuit devices. Once personalized, a wafer is set with a regular repeating pattern, such as shown in FIG. 6. FIG. 6 illustrates a pattern based upon a capacitive chip size pattern seen in detailed view 610. The various sizes of patterns shown in detailed view 610 (e.g. 611, 612, or 613) can be employed, and would have corresponding dicing channels utilized for cutting into respective capacitive chip sizes.

The method also includes forming (702) capacitance zones comprising sets of capacitance elements having shared terminals. Each of the capacitance zones are formed by coupling terminals of predetermined quantities of individual capacitance elements into commonly connected collections of capacitance elements. For example, positive terminals of a set of capacitance elements can be coupled together, and negative terminals of that set of capacitance elements can be coupled together. The capacitance zones might have a predetermined rectangular/square size, such as having sides of 1 mm, 0.5 mm, or other sizes. Capacitance zones might be larger or smaller than the above example, and multiple zones might be used to suit the target integrated circuit device. For example, SoC devices can have many processing/graphics cores that have on-die voltage regulation unique to each core, mainly with lower power SoC applications. Zones can be custom-sized according to these applications and the target integrated circuit devices.

In some examples, the capacitance zones provide for integrated capacitance analogues to discrete capacitors, although implementations can vary. The coupling of capacitance elements into zones can occur via interconnect formed into the semiconductor wafer, which might be embedded with the capacitance elements or formed on one or more separate metallization layers, including combinations thereof. These capacitance zones can be formed to comprise a repeating or regular array of zones over the entire functional portion of the wafer, making a gridded arrangement of zones each having the same or similar size.

In addition to forming collections of capacitance elements to form the grid of capacitance zones, customized groups of zones can be further coupled together to form (703) capacitance domains. These capacitance domains typically correspond to a power/voltage domain arrangement of a target integrated circuit device and are formed to connect to TSVs of the target integrated circuit device. One or more metallization layers can be formed over the wafer to form these capacitance domains as well as external conductive pads. In this manner, a wafer can be formed having a regular array of capacitance elements grouped into a grid of capacitance zones. A common wafer design can be employed for all various personalization or customization implementations, with only one or more metallization layers customized to form capacitance domains and conductive pads. Capacitance elements formed within dicing channels can be coupled into capacitance domains or capacitance zones using the one or more personalization metallization layers.

Once the wafer has been formed, then the wafer can be cut (704) along selected dicing channels to form individual capacitance dies. These individual capacitance dies can be coupled to TSVs of a target integrated circuit device through one or more solder features, such as C4 solder balls. In this manner, the capacitance chip or die can be bonded (705) to corresponding integrated circuit devices. Various heat sink elements can be coupled to the stackup formed by a capacitance die and a die from a target integrated circuit device. Thermally conductive material can be disposed between the heat sink and the capacitance die.

Certain inventive aspects may be appreciated from the foregoing disclosure, of which the following are various examples.

### Example 1

An assembly, comprising an integrated circuit device comprising a plurality of through silicon vias (TSVs) coupled to corresponding voltage domains of the integrated circuit device, and one or more capacitive elements external to the integrated circuit device and conductively coupled to selected ones of the TSVs.

### Example 2

The assembly of Example 1, where the one or more capacitive elements comprise decoupling capacitors coupled between pairs of the selected ones of the TSVs corresponding to the voltage domains and at least a reference potential.

### Example 3

The assembly of Examples 1-2, comprising the one or more capacitive elements comprising a semiconductor capacitor array positioned onto the integrated circuit device to conductively couple to the selected ones of the TSVs.

### Example 4

The assembly of Examples 1-3, comprising conductive pads on the semiconductor capacitor array configured to couple to the selected ones of the TSVs via solder bumps.

### Example 5

The assembly of Examples 1-4, comprising the semiconductor capacitor array comprising an integrated array of one or more among silicon capacitance elements, metal-oxide-semiconductor capacitance elements, and metal-insulator-semiconductor capacitance elements.

### Example 6

The assembly of Examples 1-5, comprising at least a metallization layer of the semiconductor capacitor array configured to form groupings of the one or more capacitance elements among the voltage domains.

### Example 7

The assembly of Example 1-6, where the integrated circuit device comprises a first minimum feature size, and where the semiconductor capacitor array comprises a second minimum feature size larger than the first minimum feature size.

### Example 8

The assembly of Example 1-7, comprising the one or more capacitive elements comprising surface mount capacitors positioned onto the integrated circuit device to conductively couple to the selected ones of the TSVs.

### Example 9

The assembly of Example 1-8, comprising at least a metallization layer of the integrated circuit device configured to couple the selected ones of the TSVs to the surface mount capacitors.

### Example 10

The assembly of Example 1-9, comprising a heat sink positioned onto at least the surface mount capacitors and comprising surface indentations in accordance with placements of the surface mount capacitors.

### Example 11

An integrated circuit arrangement, comprising a system-on-a-chip (SoC) device comprising a plurality of voltage domains coupled to through silicon vias (TSVs), and capacitive elements positioned onto a surface of the SoC device and conductively coupled to selected TSVs.

### Example 12

The integrated circuit arrangement of Example 11, comprising the capacitive elements comprising an integrated array of semiconductor capacitors positioned onto the surface of the SoC device.

### Example 13

The integrated circuit arrangement of Examples 11-12, comprising conductive pads on the integrated array configured to conductively couple the capacitance elements to the selected TSVs via solder bumps.

### Example 14

The integrated circuit arrangement of Examples 11-13, comprising at least a metallization layer of the integrated array configured to couple groupings of the TSVs among the voltage domains to the semiconductor capacitors.

### Example 15

The integrated circuit arrangement of Examples 11-14, where the SoC device comprises a first minimum feature size, and where the integrated array comprises a second minimum feature size larger than the first minimum feature size.

### Example 16

The integrated circuit arrangement of Examples 11-15, comprising the capacitive elements comprising surface mount capacitors positioned onto the surface of the SoC device to conductively couple to the selected TSVs.

### Example 17

The integrated circuit arrangement of Examples 11-16, comprising at least a metallization layer of the SoC device configured to couple the selected TSVs to the surface mount capacitors.

### Example 18

The integrated circuit arrangement of Examples 11-17, comprising a heat sink positioned onto the surface mount capacitors and comprising surface indentations in accordance with placement of the surface mount capacitors.

### Example 19

A semiconductor capacitance device, comprising an integrated array of semiconductor capacitors, a metallization layer configured to conductively couple selected semiconductor capacitors into voltage domain groupings, and conductive pads disposed on a surface of the semiconductor capacitor device and configured to couple to through silicon via (TSV) features of an external integrated circuit.

### Example 20

The semiconductor capacitance device of Example 19, comprising a gridded arrangement of the semiconductor capacitors forming the integrated array and having dicing channels of the semiconductor capacitance device positioned between individual rows and columns of the gridded arrangement.

The functional block diagrams, operational scenarios and sequences, and flow diagrams provided in the Figures are representative of exemplary systems, environments, and methodologies for performing novel aspects of the disclosure. While, for purposes of simplicity of explanation, methods included herein may be in the form of a functional diagram, operational scenario or sequence, or flow diagram, and may be described as a series of acts, it is to be understood and appreciated that the methods are not limited by the order of acts, as some acts may, in accordance therewith, occur in a different order and/or concurrently with other acts from that shown and described herein. For example, those skilled in the art will understand and appreciate that a method could alternatively be represented as a series of interrelated states or events, such as in a state diagram. Moreover, not all acts illustrated in a methodology may be required for a novel implementation.

The descriptions and figures included herein depict specific implementations to teach those skilled in the art how to make and use the best option. For the purpose of teaching inventive principles, some conventional aspects have been simplified or omitted. Those skilled in the art will appreciate variations from these implementations that fall within the scope of the invention. Those skilled in the art will also appreciate that the features described above can be combined in various ways to form multiple implementations. As a result, the invention is not limited to the specific implementations described above, but only by the claims and their equivalents.

What is claimed is:

1. An assembly, comprising:
an integrated circuit device comprising a plurality of through silicon vias (TSVs) coupled to corresponding voltage domains of the integrated circuit device; and
one or more capacitive elements external to the integrated circuit device and conductively coupled to selected ones of the TSVs.

2. The assembly of claim 1, wherein the one or more capacitive elements comprise decoupling capacitors coupled between pairs of the selected ones of the TSVs corresponding to the voltage domains and at least a reference potential.

3. The assembly of claim 1, comprising:
the one or more capacitive elements comprising a semiconductor capacitor array positioned onto the integrated circuit device to conductively couple to the selected ones of the TSVs.

4. The assembly of claim 3, comprising:
conductive pads on the semiconductor capacitor array configured to couple to the selected ones of the TSVs via solder bumps.

5. The assembly of claim 3, comprising:
the semiconductor capacitor array comprising an integrated array of one or more among silicon capacitance elements, metal-oxide-semiconductor capacitance elements, and metal-insulator-semiconductor capacitance elements.

6. The assembly of claim 3, comprising:
at least a metallization layer of the semiconductor capacitor array configured to form groupings of the one or more capacitance elements among the voltage domains.

7. The assembly of claim 3, wherein the integrated circuit device comprises a first minimum feature size, and wherein the semiconductor capacitor array comprises a second minimum feature size larger than the first minimum feature size.

8. The assembly of claim 1, comprising:
the one or more capacitive elements comprising surface mount capacitors positioned onto the integrated circuit device to conductively couple to the selected ones of the TSVs.

9. The assembly of claim 8, comprising:
at least a metallization layer of the integrated circuit device configured to couple the selected ones of the TSVs to the surface mount capacitors.

10. The assembly of claim 8, comprising:
a heat sink positioned onto at least the surface mount capacitors and comprising surface indentations in accordance with placements of the surface mount capacitors.

11. An integrated circuit arrangement, comprising:
a system-on-a-chip (SoC) device comprising a plurality of voltage domains coupled to through silicon vias (TSVs); and
capacitive elements positioned onto a surface of the SoC device and conductively coupled to selected TSVs.

12. The integrated circuit arrangement of claim 11, comprising:
the capacitive elements comprising an integrated array of semiconductor capacitors positioned onto the surface of the SoC device.

13. The integrated circuit arrangement of claim 12, comprising:
conductive pads on the integrated array configured to conductively couple the capacitance elements to the selected TSVs via solder bumps.

14. The integrated circuit arrangement of claim 12, comprising:
at least a metallization layer of the integrated array configured to couple groupings of the TSVs among the voltage domains to the semiconductor capacitors.

15. The integrated circuit arrangement of claim 12, wherein the SoC device comprises a first minimum feature size, and wherein the integrated array comprises a second minimum feature size larger than the first minimum feature size.

16. The integrated circuit arrangement of claim 11, comprising:
the capacitive elements comprising surface mount capacitors positioned onto the surface of the SoC device to conductively couple to the selected TSVs.

17. The integrated circuit arrangement of claim 16, comprising:
at least a metallization layer of the SoC device configured to couple the selected TSVs to the surface mount capacitors.

18. The integrated circuit arrangement of claim 16, comprising:
a heat sink positioned onto the surface mount capacitors and comprising surface indentations in accordance with placement of the surface mount capacitors.

19. A semiconductor capacitance device, comprising:
an integrated array of semiconductor capacitors;
a metallization layer configured to conductively couple selected semiconductor capacitors into voltage domain groupings;
conductive pads disposed on a surface of the semiconductor capacitor device and configured to couple to through silicon via (TSV) features of an external integrated circuit.

20. The semiconductor capacitance device of claim 19, comprising:
a gridded arrangement of the semiconductor capacitors forming the integrated array and having dicing channels of the semiconductor capacitance device positioned between individual rows and columns of the gridded arrangement.
